(19) United States
(12) Patent Application Publication
(10) Pub. No.: US 2025/0017045 A1
(43) Pub. Date: Jan. 9, 2025

(54) DISPLAY DEVICE AND METHOD OF MANUFACTURING DISPLAY DEVICE

(71) Applicant: Samsung Display Co., LTD., Yongin-si (KR)

(72) Inventor: Hyun Eok SHIN, Yongin-si (KR)

(21) Appl. No.: 18/432,328

(22) Filed: Feb. 5, 2024

(30) Foreign Application Priority Data
Jul. 6, 2023 (KR) 10-2023-0087839

(51) Int. Cl. H10K 59/122; H10K 59/12

(52) U.S. Cl. CPC H10K 59/122; H10K 59/1201

(57) ABSTRACT

A display device may include a pixel circuit layer, a partition wall above the pixel circuit layer, a protrusion part spaced apart from the partition wall in a planar direction, and defining an opening, a planarization layer in the opening, a first electrode having at least a portion above the planarization layer, a light-emitting part having at least a portion above the first electrode, and a second electrode having at least a portion above the light-emitting part.

### CROSS-REFERENCE TO RELATED APPLICATION

The present application claims priority to, and the benefit of, Korean Patent Application No. 10-2023-0087839, filed on Jul. 6, 2023, in the Korean Intellectual Property Office, the entire disclosure of which is incorporated herein by reference.

### BACKGROUND

### 1. Technical Field

The disclosure generally relates to a display device, and to a method of manufacturing a display device.

### 2. Description of the Related Art

Recently, as interest in information displays is increased, research and development of display devices have been continuously conducted. For example, as demand for high-quality display devices increases, discussion on display devices including a light-emitting element having a micro scale or nano scale size has been actively made. The light-emitting element may include an anode electrode, a light-emitting part, and a cathode electrode.

A display device including a light-emitting element having a micro scale or nano scale size may include inter-pixel partition walls defining an area in which a light-emitting part is located. The light-emitting part may be deposited between the inter-pixel partition walls. When the light-emitting part is deposited between the inter-pixel partition walls, a shadow effect may occur due to the structure of the inter-pixel partition walls, and therefore, the light-emitting part may not be formed in at least a portion of the area. This may narrow the area in which the light-emitting deposited. In addition, light emitted from the light-emitting part is blocked by the structure of the inter-pixel partition walls, and therefore, the light emission efficiency of the display device may be reduced.

Accordingly, a display device is required, in which a light-emitting part is appropriately formed in a relatively wide area, so that the light emission efficiency of the display device is improved.

### SUMMARY

Embodiments provide a display device, and a method of manufacturing a display device, which can improve the light emission efficiency of the display device while a light-emitting part is formed in a relatively wide area.

In accordance with an aspect of the present disclosure, there is provided a display device including a pixel circuit layer, a partition wall above the pixel circuit layer, a protrusion part spaced apart from the partition wall in a planar direction, and defining an opening, a planarization layer in the opening, a first electrode having at least a portion above the planarization layer, a light-emitting part having at least a portion above the first electrode, and a second electrode having at least a portion above the light-emitting part.

The partition wall may include a first partition wall layer above the pixel circuit layer, and a second partition wall layer above the first partition wall layer.

A width the first partition wall layer may be less than a width of the second partition wall layer.

The first partition wall layer may include aluminum (Al) or molybdenum (Mo), wherein the second partition wall layer includes titanium (Ti).

The protrusion part may have a same height as the first partition wall layer.

The protrusion part and the first partition wall layer may include a same material.

The protrusion part may include a first protrusion part above the pixel circuit layer, and a second protrusion part above the first protrusion part, wherein the first protrusion part has a same height as the first partition wall layer, and wherein the second protrusion part has a same height as the second partition wall layer.

The first protrusion part and the first partition wall layer may include a same material, wherein the second protrusion part and the second partition wall layer include a same material.

The planarization layer may fill the opening, may include one flat surface, and may include an organic material.

A difference between a thickness of the planarization layer and a thickness of the protrusion part may be about 0 Å to about 1000 Å.

The first electrode and the protrusion part may be electrically connected to each other.

In accordance with another aspect of the present disclosure, there is provided a display device including a pixel circuit layer, a partition wall above the pixel circuit layer, and including a first partition wall layer, and a second partition wall layer above the first partition wall layer, a protrusion part spaced apart from the partition wall in a planar direction, and having a flat surface spaced from the pixel circuit layer, a first electrode having at least a portion above the protrusion part, a light-emitting part having at least a portion above the first electrode, and a second electrode having at least a portion above the light-emitting part.

The protrusion part and the partition wall may be at a same plane.

The first partition wall layer and the protrusion part may include aluminum (Al), wherein the first electrode entirely overlaps with the protrusion part in a plan view.

In accordance with still another aspect of the present disclosure, there is provided a method of manufacturing a display device, the method including forming a partition wall and a protrusion part above a pixel circuit layer, and spaced apart in a planar direction, in a single process, forming a first electrode above the protrusion part, forming a light-emitting part above the first electrode, and forming a second electrode above the light-emitting part.

The forming of the partition wall and the protrusion part may include depositing a first auxiliary layer above the pixel circuit layer, depositing a second auxiliary layer above the first auxiliary layer, etching the first auxiliary layer to form a first partition wall layer and the protrusion part on the pixel circuit layer, and etching the second auxiliary layer to form a second partition wall layer above the first partition wall layer, wherein the partition wall includes the first partition wall layer and the second partition wall layer, and wherein the first partition wall layer is etched more inwardly than the second partition wall layer.

The forming of the partition wall and the protrusion part may include depositing a first auxiliary layer above the pixel circuit layer, depositing a second auxiliary layer above the first auxiliary layer, etching the first auxiliary layer to form a first partition wall layer and a first protrusion part above the pixel circuit layer, and etching the second auxiliary layer to form a second partition wall layer above the first partition wall layer and to form a second protrusion part on the first protrusion part, and wherein the first protrusion part and the second protrusion part define an opening.

The method may further include forming a planarization layer in an opening defined by the protrusion part by depositing the planarization layer such that the planarization layer and the protrusion part have a thickness difference of about 0 Å to about 1000 Å.

The forming the first electrode may include depositing the first electrode above the protrusion part such that at least a portion of one surface of the first electrode is spaced apart from the pixel circuit layer.

The method may further include forming a pixel-defining layer including an inorganic material above the first electrode by depositing the pixel-defining layer above the first electrode, and etching the pixel-defining layer to expose at least a portion of the first electrode.

### BRIEF DESCRIPTION OF THE DRAWINGS

FIG. 1 is a schematic plan view illustrating a display device in accordance with one or more embodiments of the present disclosure.

FIG. 2 is a schematic sectional view illustrating a display device in accordance with one or more embodiments of the present disclosure.

FIG. 3 is a schematic sectional view illustrating a light-emitting element in accordance with one or more embodiments of the present disclosure.

FIG. 4 is a schematic block diagram illustrating an electrical connection structure of a light-emitting element in accordance with one or more embodiments of the present disclosure.

FIG. 5 is a schematic sectional view illustrating a display device in accordance with first embodiments of the present disclosure.

FIG. 6 is a schematic plan view illustrating a position relationship between a protrusion part and a planarization layer in accordance with the first embodiments of the present disclosure.

FIG. 7 is a schematic sectional view illustrating a display device in accordance with second embodiments of the present disclosure.

FIG. 8 is a schematic sectional view illustrating a display device in accordance with third embodiments of the present disclosure.

FIG. 9 is a flowchart illustrating a method of manufacturing the display device in accordance with each of the first embodiments and the second embodiments of the present disclosure.

FIGS. 10 to 16 are schematic sectional views illustrating process operations according to the method of manufacturing the display device in accordance with the first embodiments of the present disclosure.

FIG. 17 is a flowchart illustrating a method of manufacturing a display device in accordance with one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have substantially the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The disclosure generally relates to a display device and a method of manufacturing a display device. Hereinafter, a display device and a method of manufacturing a display device in accordance with one or more embodiments of the present disclosure will be described with reference to the accompanying drawings.

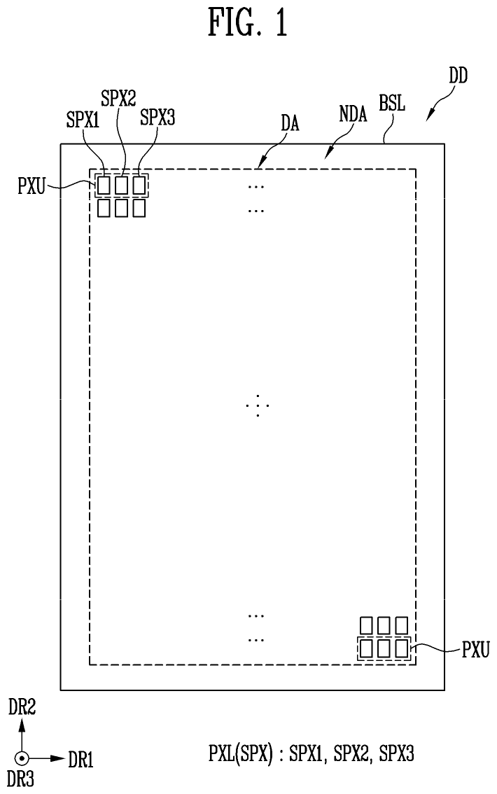

FIG. 1 is a schematic plan view illustrating a display device in accordance with one or more embodiments of the present disclosure.

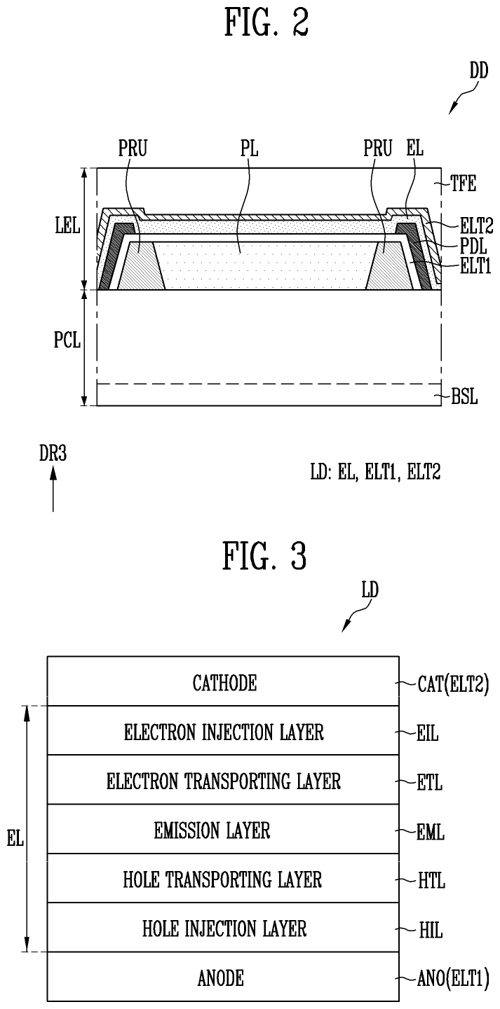

Referring to FIG. 1, the display device DD may be configured to emit light. The display device DD may include a light-emitting element LD (see FIG. 2). In some embodiments, the display device DD may be a device which displays moving images or still images. The display device DD may be used as a display screen of not only portable electronic devices, such as a mobile phone, a smart phone, a tablet personal computer (PC), a smart watch, and a watch phone, but also of various products, such as a television, a notebook computer, a monitor, an advertisement board, Internet of things (IoT), and a micro display. However, the application field of the display device DD is not limited to a specific example.

The display device DD may be formed in a rectangular plane having short sides in a first direction DR1 and long sides in a second direction DR2 crossing the first direction DR1. A corner at which the short side in the first direction DR1 and the long side in the second direction DR2 meet each other may be formed round to have a curvature (e.g., predetermined curvature), or may be formed at a substantially right angle. The planar shape of the display device DD is not limited to a quadrangular shape, and the display device DD may be formed in a round shape, such as another polygonal shape, a circular shape, or an elliptical shape. The display device DD may be formed flat, but the present disclosure is not limited thereto. For example, the display device DD may include a curved part which is formed at a left/right end and has a constant curvature or a changing curvature. In addition, the display device DD may be formed flexible enough to be warpable, curvable, bendable, foldable, or rollable.

In the present disclosure, the first direction DR1 may be a “horizontal” direction as a row direction of pixels PXL. The second direction DR2 may be a “vertical” direction as a column direction of pixels PXL. A third direction DR3 may be a display direction of the display device DD, or a normal direction of a plane on which a base layer BSL is located.

The display device DD may include a display area DA and a non-display area NDA. The non-display area NDA may mean an area not including the display area DA. The non-display area NDA may surround at least a portion of the display area DA (e.g., in plan view).

The display area DA may mean an area in which pixels PXL are located. The non-display area NDA may mean an area in which the pixels PXL are not located. A driving circuit, lines, and pads, which are connected to the pixels PXL of the display area DA, may be located in the non-display area NDA.

In some embodiments, each pixel PXL (or sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may constitute one pixel unit PXU capable of emitting lights of various colors. In FIG. 1, it is illustrated that each pixel PXL includes three sub-pixels SPX1, SPX2, and SPX3 (e.g., a first sub-pixel SPX1, a second sub-pixel SPX2, and a third sub-pixel SPX3). The present disclosure is not limited thereto.

In some embodiments, the pixels PXL (or sub-pixels SPX) may be arranged according to a stripe arrangement structure, a PENTILE™ arrangement structure (e.g., a RGBG matrix structure, a PENTILE™ matrix structure, a PENTILE™ structure, or an RGBG structure, PENTILE™ being a registered trademark of Samsung Display Co., Ltd., Republic of Korea), or the like. However, the present disclosure is not limited thereto.

The first sub-pixel SPX1 may emit first light, the second sub-pixel SPX2 may emit second light, and the third sub-pixel SPX3 may emit third light. The first light may be light in a red wavelength band, the second light may be light in a green wavelength band, and the third light may be light in a blue wavelength band. The red wavelength band may be a wavelength band of about 600 nm to about 750 nm, the green wavelength band may be a wavelength band of about 480 nm to about 560 nm, and the blue wavelength band may be a wavelength band of about 370 nm to about 460 nm. However, the present disclosure is not limited thereto.

Each of the first sub-pixel SPX1, the second sub-pixel SPX2, and the third sub-pixel SPX3 may include, as a light-emitting element emitting light, an inorganic light-emitting diode including an inorganic semiconductor or an organic light-emitting diode (OLED). However, the present disclosure is not limited to a specific example.

FIG. 2 is a schematic sectional view illustrating a display device in accordance with one or more embodiments of the present disclosure. FIG. 3 is a schematic sectional view illustrating a light-emitting element in accordance with one or more embodiments of the present disclosure.

Referring to FIGS. 2 and 3, the display device DD includes a pixel circuit layer PCL and a light-emitting element layer LEL.

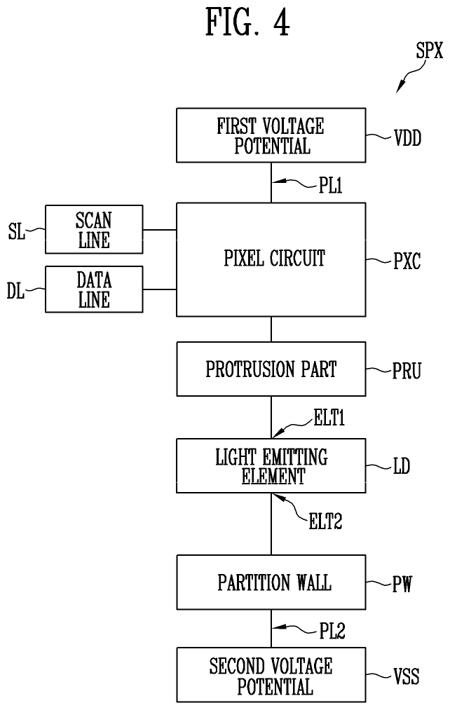

The pixel circuit layer PCL may include a pixel circuit PXC (see FIG. 4) for driving light-emitting elements LD. The pixel circuit layer PCL may include a base layer BSL, conductive layers for forming pixel circuits, and insulating layers located on the conductive layers.

In some embodiments, the pixel circuit PXC may include a thin film transistor, and may be electrically connected to light-emitting elements LD to provide an electrical signal for allowing the light-emitting elements LD to emit light.

The light-emitting element layer LEL may be located on the pixel circuit layer PCL. In some embodiments, the light-emitting element layer LEL may include a protrusion part PRU, a planarization layer PL, a light-emitting element LD, a pixel-defining layer PDL, and an encapsulation layer TFE.

The protrusion part PRU and the planarization layer PL may be located on the pixel circuit layer PCL. The protrusion part PRU and the planarization layer PL may be located directly on the pixel circuit layer PCL. The protrusion part PRU and the planarization layer PL may protrude in a thickness direction (e.g., the third direction DR3) of the base layer BSL.

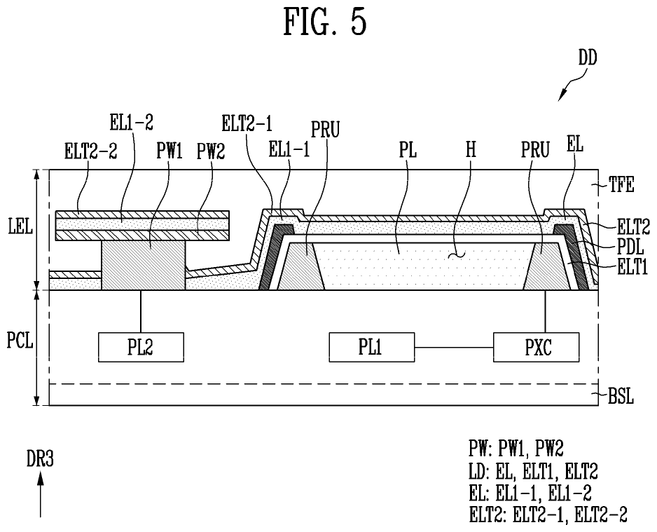

The protrusion part PRU and the planarization layer PL may allow the light-emitting element LD (e.g., a light-emitting part EL) to be located at a higher position. Structural features related to this will be described later with reference to the drawings from FIG. 5.

The protrusion part PRU may include a conductive material. For example, the protrusion part PRU may include at least one selected from the group consisting of gold (Au), silver (Ag), aluminum (Al), molybdenum (Mo), chromium (Cr), titanium (Ti), nickel (Ni), neodymium (Nd), copper (Cu), and/or platinum (Pt). The protrusion part PRU includes the conductive material to serve as a conduction path for supplying an anode signal provided from the pixel circuit PXC (see FIG. 4) to the light-emitting element LD.

The light-emitting element LD may be located on the pixel circuit layer PCL. The light-emitting element LD may be located on the protrusion part PRU and the planarization layer PL. In a plan view, the light-emitting element LD may overlap with the protrusion part PRU, and may overlap with the planarization layer PL.

In some embodiments, the light-emitting element LD may include a first electrode ELT1, the light-emitting part EL, and a second electrode ELT2.

One surface of the light-emitting part EL may be electrically connected to the first electrode ELT1, and the other surface of the light-emitting part EL may be electrically connected to the second electrode ELT2.

The first electrode ELT1 may be an anode electrode ANO with respect to the light-emitting part EL, and the second electrode ELT2 may be a cathode electrode CAT with respect to the light-emitting part EL. In some embodiments, the first electrode ELT1 and the second electrode ELT2 may include a conductive material. For example, the first electrode ELT1 may include a conductive material including reflexibility, and the second electrode ELT2 may include a transparent conductive material. However, the present disclosure is not necessarily limited thereto. The first electrode ELT1 may be the cathode electrode CAT with respect to the light-emitting part EL, and the second electrode ELT2 may be the anode electrode ANO with respect to the light-emitting part EL.

The light-emitting part EL may have a multi-layer thin film structure including a light generation layer (e.g., an emission layer EML). The light-emitting part EL may include a hole injection layer HIL for injecting holes, a hole transport layer HTL for increasing a hole recombination opportunity by suppressing movement of electrons, which are excellent in transportability of holes and which are not combined in the emission layer EML, the emission layer EML for emitting light by recombination of the injected electrons and holes, an electron transport layer ETL for smoothly transporting the electrons to the light generation layer, and an electron injection layer EIL for injecting the electrons. The light-emitting part EL may emit light, based on an electrical signal provided from the anode electrode ANO (e.g., the first electrode ELT1) and the cathode electrode CAT (e.g., the second electrode ELT2).

At least a portion of the first electrode ELT1 may be located on the protrusion part PRU and the planarization layer PL. At least a portion of the first electrode ELT1 may be located directly on the protrusion part PRU and the planarization layer PL. At least a portion of the first electrode ELT1 may cover the protrusion part PRU and the planarization layer PL.

The pixel-defining layer PDL may be located on the first electrode ELT1. The pixel-defining layer PDL may be located on (e.g., above) the protrusion part PRU. The pixel-defining layer PDL may be located on the protrusion part PRU to define a position at which the light-emitting part EL is located. For example, the pixel-defining layer PDL may cover one end portion of the protrusion part PRU, and may define a position at which the light-emitting element EL is located on the planarization layer. The pixel-defining layer PDL may expose at least a portion of the first electrode ELT1. The pixel-defining layer PDL may not overlap with at least a portion of the protrusion part PRU in a plan view.

The pixel-defining layer PDL may include an inorganic material. For example, the inorganic material may include at least one selected from the group consisting of silicon nitride (SiNₓ), silicon oxide (SiOₓ), silicon oxynitride (SiOₓN_{y}), and/or aluminum oxide (AlOₓ). However, the present disclosure is not limited thereto. The pixel-defining layer PDL may include an organic material. For example, the pixel-defining layer PDL may include at least one selected from the group consisting of acrylic resin, epoxy resin, phenolic resin, polyamide resin, and/or polyimide resin.

At least a portion of the second electrode ELT2 may be located on the light-emitting part EL. At least a portion of the second electrode ELT2 may be located directly on the light-emitting part EL. At least a portion of the second electrode ELT2 may cover the light-emitting part EL.

The encapsulation layer TFE may be located over the light-emitting element LD (e.g., the second electrode ELT2). The encapsulation layer TFE may reduce or eliminate a step difference caused by the light-emitting element LD and the pixel-defining layer PDL. The encapsulation layer TFE may include a plurality of insulating layers covering the light-emitting element LD. In some embodiments, the encapsulation layer TFE may have a structure in which an inorganic layer and an organic layer are alternately stacked. In some embodiments, the encapsulation layer TFE may be a thin film encapsulation layer.

FIG. 4 is a schematic block diagram illustrating an electrical connection structure of a light-emitting element in accordance with one or more embodiments of the present disclosure. For example, FIG. 4 may illustrate an electrical connection structure including a pixel circuit PXC corresponding to each sub-pixel SPX.

Referring to FIG. 4, the sub-pixel SPX may include a pixel circuit PXC configured to drive a light-emitting element LD.

The pixel circuit PXC may include at least one circuit element. For example, the pixel circuit PXC may include transistors and a storage capacitor. For example, the pixel circuit PXC may include a driving transistor, a switching transistor, and a storage capacitor. However, the present disclosure is not necessarily limited thereto.

The pixel circuit PXC may be electrically connected to a scan line SL and a data line DL. The scan line SL may supply a scan signal to the pixel circuit PXC. In some embodiments, the scan line SL may be electrically connected to a gate electrode of the switching transistor of the pixel circuit PXC. The light-emitting element LD may be configured to emit light corresponding to a data signal provided from the data line DL.

The pixel circuit PXC may be electrically connected to a first power line PL1 and a second power line PL2. For example, a first electrode ELT1 of the light-emitting element LD may be electrically connected to the pixel circuit PXC and to the first power line PL1, and a second electrode ELT2 of the light-emitting element LD may be electrically connected to the second power line PL2. In some embodiments, the second power line PL2 may be formed in the pixel circuit layer PCL in the display area DA. Alternatively, in other embodiments, the second power line PL2 may be located in the non-display area NDA. Accordingly, the second power line PL2 may be configured to supply a second power source to the light-emitting element LD.

A power source of the first power line PL1 and a power source of the second power line PL2 may have different potentials. For example, the power source of the first power line PL1 may be a high-potential pixel power source supplied with a power source from a first voltage potential VDD, and the power source of the second power line PL2 may be a low-potential pixel power source supplied with a power source from a second voltage potential VSS. A potential difference between the power source of the first power line PL1 and the power source of the second power line PL2 may be set to be equal to or higher than a threshold voltage of light-emitting elements LD.

The first power line PL1 may be electrically connected to the pixel circuit PXC (e.g., the driving transistor). The second power line PL2 may be electrically connected to a cathode electrode (e.g., the second electrode ELT2) of the light-emitting element LD.

In some embodiments, the first power line PL1 may be electrically connected to the first electrode ELT1 through the pixel circuit PXC and a protrusion part PRU. In some embodiments, the protrusion part PRU may serve as a conduction path for supplying an anode signal provided from the pixel circuit PXC. For example, the protrusion part PRU may electrically connect the first electrode ELT1 to the pixel circuit PXC of the pixel circuit layer PCL.

In some embodiments, the second power line PL2 may be electrically connected to the second electrode ELT2 through a partition wall PW. In some embodiments, the partition wall PW may serve as a conduction path for supplying a cathode signal provided from the second electrode ELT2. For example, the partition wall PW may electrically connect the second electrode ELT2 and the second power line PL2 to each other. The partition wall PW will be described later with reference to FIG. 5.

Light emitting elements LD may be connected in a forward direction between the first power line PL1 and the second power line PL2 to respectively form effective light sources. These effective light sources collectively constitute the light-emitting elements LD of the sub-pixel SPX.

The light-emitting elements LD may emit light with a luminance corresponding to a driving current supplied through the pixel circuit PXC. The pixel circuit PXC may supply a driving current corresponding to the data signal to the light-emitting element LD during each frame period. The light-emitting element LD may emit light with a luminance corresponding to a current flowing therethrough.

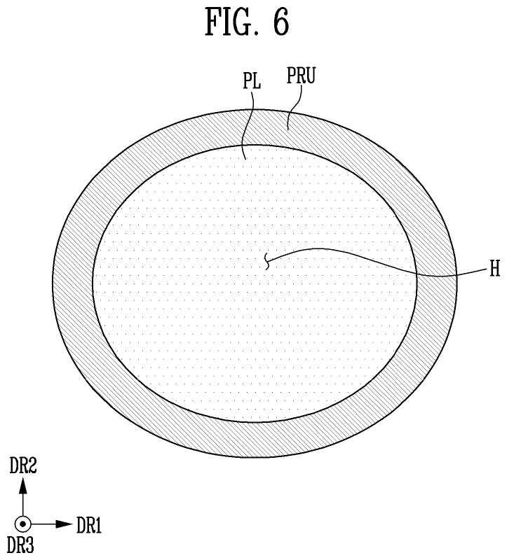

Hereinafter, structural features of a partition wall PW and a protrusion part PRU of a display device DD in accordance with first embodiments of the present disclosure will be described with reference to FIGS. 5 and 6. In FIGS. 5 and 6, descriptions of portions overlapping with those described above will not be repeated.

FIG. 5 is a schematic sectional view illustrating a display device in accordance with first embodiments of the present disclosure. FIG. 6 is a schematic plan view illustrating a position relationship between a protrusion part and a planarization layer in accordance with the first embodiments of the present disclosure.

Referring to FIG. 5, a light-emitting element layer LEL of the display device DD in accordance with the first embodiments of the present disclosure may include a protrusion part PRU, a planarization layer PL, a light-emitting element LD, a pixel-defining layer PDL, and an encapsulation layer TFE, and may further include a partition wall PW.

The partition wall PW may be located on the pixel circuit layer PCL. In some embodiments, the partition wall PW may have a multi-layer structure. For example, the partition wall may have a multi-layer structure including a first partition wall layer PW1 and a second partition wall layer PW2 located on the first partition wall layer PW1. Hereinafter, for convenience of description, one or more embodiments in which the partition wall PW has a double-layer structure including the first partition wall layer PW1 and the second partition wall layer PW2 will be mainly described. However, the present disclosure is not limited thereto.

The partition wall PW may have a structure in which the second partition wall layer PW2 protrudes outwardly further than the first partition wall layer PW1. For example, the partition wall PW may have a ‘T’-shaped structure. The first partition wall layer PW1 may have a width that is narrower than a width of the second partition wall layer PW2. The first partition wall layer PW1 may have a thickness that is thicker than a thickness of the second partition wall layer PW2.

In the present disclosure, a width may be defined with respect to a direction (e.g., the first direction DR1 and/or the second direction DR2) in which a plane on which the pixel circuit layer PCL is located extends (e.g., a planar direction), and a thickness may be defined with respect to a thickness direction (e.g., the third direction DR3) of the pixel circuit layer PCL.

The partition wall PW may include a metal material. For example, the metal material may include at least one selected from the group consisting of gold (Au), silver (Ag), aluminum (Al), molybdenum (Mo), chromium (Cr), titanium (Ti), nickel (Ni), neodymium (Nd), copper (Cu), and/or platinum (Pt). In some embodiments, the first partition wall layer PW1 may include aluminum (Al) or molybdenum (Mo). In some embodiments, the second partition wall layer PW2 may include titanium (Ti). However, the present disclosure is not limited thereto.

The protrusion part PRU may be located on the pixel circuit layer PCL. The protrusion part PRU may be spaced apart from the partition wall PW in a width direction of the partition wall PW. The protrusion part PRU may be located on the same plane as the partition wall PW. The protrusion part PRU and the partition wall PW may be in contact with one surface (e.g., a top surface) of the pixel circuit layer PCL.

Referring to FIG. 6, the protrusion part PRU may include (e.g., may define) an opening H. For example, when viewed in an upper direction (e.g., the third direction DR3) of the display device DD, the protrusion part PRU may have the shape of a circle including/defining the opening H. For example, the protrusion part PRU may have a doughnut shape in a plan view. However, the present disclosure is not limited thereto. The protrusion part PRU may have the shape of a polygon including the opening H.

The protrusion part PRU may be formed through the same process as the first partition wall layer PW1. The protrusion part PRU may have substantially the same thickness as the first partition wall layer PW1. The protrusion part PRU may include the same material as the first partition wall layer PW1. The protrusion part PRU may include a metal layer. In some embodiments, the protrusion part PRU may include aluminum (Al) or molybdenum (Mo).

The protrusion part PRU may be in contact with a first electrode ELT1. The protrusion part PRU may electrically connect the pixel circuit PXC of the pixel circuit layer PCL and the first electrode ELT1 to each other. Accordingly, any contact hole connecting the pixel circuit PXC and the first electrode ELT1 to each other need not be separately formed between the protrusion part PRU and the first electrode ELT1.

The planarization layer PL may be located inside the protrusion part PRU. The planarization layer PL may be located in the opening H of the protrusion part PRU. The planarization layer PL may fill the opening H of the protrusion part PRU. The planarization layer PL may be in contact with the protrusion part PRU. The protrusion part PRU may surround the planarization layer PL.

The planarization layer PL may include an organic material. In some embodiments, the planarization layer PL may include at least one selected from the group consisting of acrylic resin, epoxy resin, phenolic resin, polyamide resin, and/or polyimide resin.

A layer including an organic material may have liquidity, or fluidity, if heat of a relatively high temperature (e.g., about 200° C. or higher) is applied to the layer after the layer is deposited. When the protruding part PRU is absent, an organic layer may be melted at a high temperature, and may flow in a direction in which the partition wall is located. When the organic layer flows, a component, such as the protrusion part PRU supporting the fluid organic layer is absent, and therefore, the organic layer may be formed to be inclined. For example, a surface of the organic layer may not be flat.

In addition, if the component supporting reduction or prevention of the flow of the organic layer is absent, the organic layer may continuously flow, and therefore, it may be difficult for the organic layer to be finely patterned. When the organic layer is not finely patterned, it may be difficult for a display to have a high resolution.

According to the presently described display device DD, the planarization layer PL may be located in the opening H of the protrusion part PRU. Therefore, the protrusion part PRU may surround the planarization layer PL, and may support the planarization layer PL. Thus, if heat of a relatively high temperature is applied to the planarization layer PL after the planarization layer PL is deposited, the planarization layer does not overflow to the outside (e.g., in a direction in which the partition wall PW is located). Accordingly, a surface of the planarization layer PL is not formed inclined. Thus, the surface of the planarization PL can be formed flat.

Because the planarization layer PL can be manufactured flat, according to the presently described display device DD, a separate Chemical Mechanical Polishing (CMP) for allowing the surface of the planarization layer PL to be substantially flat need not be performed.

Experimentally, if the light-emitting element LD is formed, it is suitable for the first electrode ELT1 to be located on a roughly flat surface. According to a conventional display structure, as a structure corresponding to the protrusion part PRU and the planarization PL of the present disclosure is absent, the first electrode ELT1 was located directly on the pixel circuit layer PCL including an insulating layer formed of an inorganic layer at an outermost portion. Because the flatness of the inorganic layer is relatively inferior, the first electrode ELT1 was located after a CMP process for allowing a surface of the inorganic layer to be flat was performed. As compared with this, the presently described first electrode ELT1 of the display device DD is located on the planarization layer PL, so that any CMP process for disposing the first electrode ELT1 is not performed.

The planarization layer PL may have substantially the same thickness as the protrusion part PRU, or may have a thickness that is thicker than a thickness of the protrusion part PRU. The planarization layer PL and the protrusion part PRU may have thicknesses similar to each other. For example, a difference of the thickness of the planarization layer PL and the thickness of the protrusion part PRU may be included in a range of about 0 Å to about 1000 Å.

The first electrode ELT1 may be located on the protrusion part PRU and the planarization layer PL. The first electrode ELT1 may entirely cover the protrusion part PRU and the planarization layer PL. The first electrode ELT1 may overlap with the protrusion part PRU and the planarization layer PL in a plan view. The first electrode ELT1 may be in contact with the protrusion part PRU and the planarization layer PL.

Both surfaces of the first electrode ELT1 may respectively include an inclined surface. As each surface of the first electrode ELT1 has the inclined surface, the first electrode ELT1 may be located to be relatively high (e.g., relatively elevated) with respect to the pixel circuit layer PCL, as compared with the conventional display structure. For example, in the conventional display structure, the first electrode ELT1 was located immediately on the pixel circuit layer PCL. The one surface of the first electrode ELT1 was entirely in contact with the pixel circuit layer PCL, and was flat.

On the other hand, the at least a portion of the one surface of the presently described first electrode ELT1 of the display device DD may be physically spaced apart from the pixel circuit layer PCL. Therefore, the first electrode ELT1 may be relatively elevated as compared with the conventional display structure. In addition, as each surface of the electrode ELT1 is inclined, a surface area of the first electrode ELT1 may be increased.

The first electrode ELT1 may have a single-layer structure or a multi-layer structure, which includes a conductive material having reflexibility. For example, the first electrode ELT1 may have a multi-layer structure in which aluminum (Al), silver (Ag), and Indium Tin Oxide (ITO) are sequentially located. Experimentally, according to physical characteristics of aluminum (Al), if aluminum (Al) is in contact with the planarization layer PL, the first electrode ELT1 may have a high adhesive property as compared with if silver (Ag) is in contact with the planarization layer PL.

The pixel-defining layer PDL may be located on the protrusion part PRU to define a position at which the light-emitting part EL is located on the protrusion part PRU. The pixel-defining layer PDL may be located on the first electrode ELT1. The pixel-defining layer PDL may expose at least a portion of the first electrode ELT1. The pixel-defining layer PDL may cover one end portion and the other end portion of the first electrode ELT1.

The pixel-defining layer PDL may include an inorganic material. For example, the inorganic material may include at least one selected from the group consisting of silicon nitride (SiNₓ), silicon oxide (SiOₓ), silicon oxynitride (SiOₓN_{y}), and/or aluminum oxide (AlOₓ).

At least a portion of the light-emitting part EL may be located on the first electrode ELT1, the pixel-defining layer PDL, and the second partition wall layer PW2. The light-emitting part EL may include a (1-1)th light-emitting part EL1-1 located on the protrusion part PRU and a (1-2)th light-emitting part EL1-2 located on the second partition wall layer PW2. The (1-1)th light-emitting part EL1-1 and the (1-2)th light-emitting part EL1-2 may be spaced apart from each other. The (1-1)th light-emitting part EL1-1 and the (1-2)th light-emitting part EL1-2 may not be connected to each other (e.g., may be electrically insulated or separated from each other). The (1-1)th light-emitting part EL1-1 may entirely cover the first electrode ELT1 and the pixel-defining layer PDL. The (1-2)th light-emitting part EL1-2 may be entirely in contact with one surface of the second partition wall layer PW2. The (1-2)th light-emitting part EL1-2 may overlap with the second partition wall layer PW2.

The light-emitting part EL may be entirely in contact with the pixel-defining layer PDL. For example, the light-emitting part EL may be in contact with one side surface of the pixel-defining layer PDL. The light-emitting part EL may expose at least a portion of a side surface of the partition wall PW. For example, the light-emitting part EL may expose at least a portion of a side surface of the first partition wall layer PW1.

As the light-emitting part EL is located on the first electrode ELT1, which is relatively elevated as compared with the conventional display structure, the light-emitting part EL, itself, may also be relatively elevated as compared with the conventional display structure. For example, in a plan view, a height of the light-emitting part EL overlapping with the planarization layer PL may be higher than a height of the first partition wall layer PW1. In the present disclosure, a height of a component of the display device DD may be defined a thickness direction (e.g., the third direction DR3) of a base layer BSL. As the light-emitting part EL entirely covers the pixel-defining layer PDL, a surface area of the light-emitting part EL can increase as compared with the conventional display structure. As the surface area of the light-emitting part EL, a light emission area can be increased, and the lifetime of the display device DD can be increased. In addition, as the light-emitting part EL having a wide surface area and the first electrode ELT1 are connected to each other, the light emission area can be increased with the same value of current.

In the conventional display structure, a height of the light-emitting part EL overlapping with the planarization layer PL in a plan view was lower than a height of the first partition wall layer PW1. Accordingly, if the light-emitting part EL was deposited, it was difficult for a deposition material of the light-emitting part EL to be formed in at least a partial area due a tip structure, or overhang, of the second partition wall layer PW2. Also, light emitted from the light-emitting part EL was blocked by the structure of the second partition wall layer PW2. In addition, because the light-emitting part EL was deposited only inside the pixel-defining layer PDL, a surface area of the light-emitting part EL was relatively small as compared with the display device DD of the present disclosure.

As the first electrode ELT1 of the present disclosure is located high (e.g., is elevated to a greater degree) as compared with the conventional display structure, a shadow effect due to the second partition wall layer PW2 can be reduced if the light-emitting part EL is deposited on the first electrode ELT1. Accordingly, an area in which the light-emitting part EL is deposited can be increased as compared with the conventional display structure, and an area in which the light-emitting part EL can emit light can be increased. In addition, a risk that light emitted from the light-emitting part EL will be blocked by the structure of the partition wall PW can be reduced. In the present disclosure, the shadow effect may mean an effect that, if a deposition material is deposited, the deposition material is not formed in at least a partial area by an obstacle overlapping with the deposition material in a deposition direction.

A second electrode ELT2 may be located on the light-emitting part EL. The second electrode ELT2 may include a (2-1)th electrode ELT2-1 located on the (1-1)th light-emitting part EL1-1, and a (2-2)th electrode ELT2-2 located on the (1-2)th light-emitting part EL1-2. The (2-1)th electrode ELT2-1 and the (2-2)th electrode ELT2-2 may be spaced apart from each other. The (2-1)th electrode ELT2-1 and the (2-2)th electrode ELT2-2 may not be connected to each other (e.g., may be electrically insulated or separated from each other). The second electrode ELT2 may entirely cover the light-emitting part EL. For example, the (2-1)th electrode ELT2-1 may be in contact with the (1-1)th light-emitting part EL1-1 located on the protrusion part PRU, the planarization layer PL, and the pixel-defining layer PDL. For example, the (2-2)th electrode ELT2-2, may be in contact with one surface of the (1-2)th light-emitting part EL located on the second partition wall layer PW2. In a plan view, the (2-2)th electrode ELT2-2 may overlap with the (1-2)th light-emitting part EL located on the second partition wall layer PW2.

The encapsulation layer TFE may be located over the light-emitting element LD (e.g., the second electrode ELT2) and the partition wall PW. The encapsulation layer TFE may cancel, or planarize, a step difference caused by the partition wall PW and the light-emitting element LD.

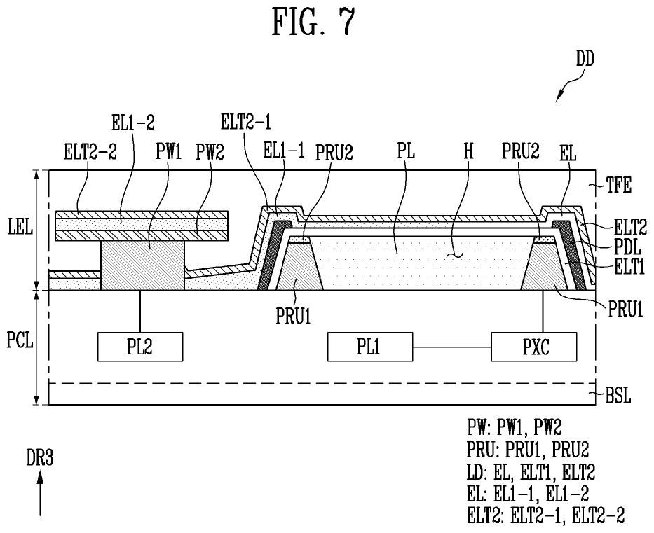

Hereinafter, structural features of a partition wall PW and a protrusion part PRU of a display device DD in accordance with second embodiments of the present disclosure will be described with reference to FIG. 7. FIG. 7 is a schematic sectional view illustrating a display device in accordance with second embodiments of the present disclosure.

The second embodiments are different from the first embodiments in that the protrusion part PRU has a multi-layer structure. In FIG. 7, descriptions of portions overlapping with those described above will not be repeated.

The protrusion part PRU in accordance with the second embodiments of the present disclosure may include a first protrusion part PRU1 and a second protrusion part PRU2. The first protrusion part PRU1 may be located on the pixel circuit layer PCL. The first protrusion part PRU1 may be in contact with the pixel circuit layer PCL. The second protrusion part PRU2 may be located on the first protrusion part PRU1. The second protrusion part PRU2 may be in contact with the first protrusion part PRU1.

The first protrusion part PRU1 may be formed through the same process as the first partition wall layer PW1. In some embodiments, the first protrusion part PRU1 may be located on the same plane as the first partition wall layer PW1. The first protrusion part PRU1 may have substantially the same thickness as the first partition wall layer PW1. The first protrusion part PRU1 may include the same material as the first partition wall layer PW1. The first protrusion part PRU1 may include a metal material. In some embodiments, the first protrusion part PRU1 may include aluminum (Al) or molybdenum (Mo).

The second protrusion part PRU2 may be formed through the same process as the second partition wall layer PW2. In some embodiments, the second protrusion part PRU2 may be located on the same plane as the second partition wall layer PW2. The second protrusion part PRU2 may have substantially the same thickness as the second partition wall layer PW2. The second protrusion part PRU2 may include the same material as the second partition wall layer PW2. The second protrusion part PRU2 may include a metal material. In some embodiments, the second protrusion part PRU2 may include titanium (Ti).

A thickness obtained by adding up the thickness of the first protrusion part PRU1 and the thickness of the second protrusion part PRU2 may be equal to or greater than a thickness of the planarization layer PL. The thickness obtained by adding up the thickness of the first protrusion part PRU1 and the thickness of the second protrusion part PRU2 may be similar to the thickness of the planarization layer PL. For example, a difference between the thickness obtained by adding up the thickness of the first protrusion part PRU1 and the thickness of the second protrusion part PRU2 and the thickness of the planarization layer PL may be included in a range of about 0 Å to about 1000 Å.

As the protrusion part PRU of the display device DD in accordance with the second embodiments of the present disclosure further includes the second protrusion part PRU2, so that the protrusion part PRU can further protrude from the pixel circuit layer PCL. As the protrusion part PRU further protrudes from the pixel circuit layer PCL, the planarization layer PL can be deposited not to overflow to the outside. Also, as the protrusion part PRU further protrudes from the pixel circuit layer PCL, in the display device DD in accordance with the second embodiments of the present disclosure, the light-emitting part EL can also be relatively high (e.g., relatively elevated) as compared with the conventional display structure. Accordingly, a shadow effect due to the structure of the second partition wall layer PW2 can be reduced if the light-emitting part EL is deposited. In addition, as a position at which the light-emitting part EL is located becomes high, a risk that light emitted from the light-emitting part EL will be blocked by the second partition wall layer PW2 can be reduced. In addition, the planarization PL is supported by the protrusion part PRU, so that a surface of the planarization layer PL can be formed flat.

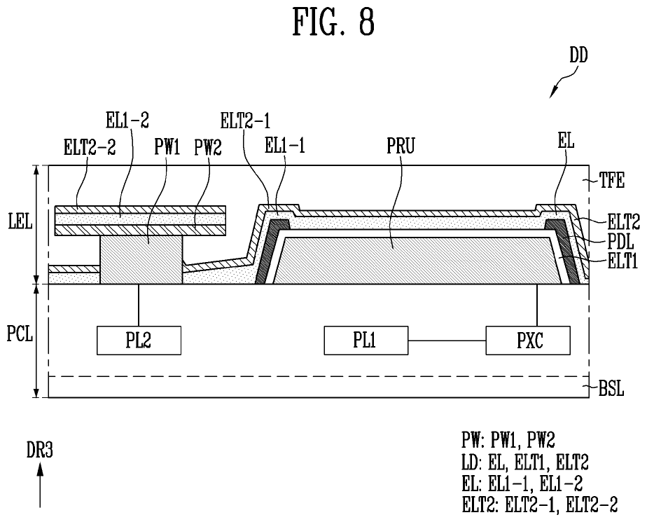

Hereinafter, structural features of a partition wall PW and a protrusion part PRU of a display device DD in accordance with third embodiments of the present disclosure will be described with reference to FIG. 8. FIG. 8 is a schematic sectional view illustrating a display device in accordance with third embodiments of the present disclosure.

The third embodiments are different from the first embodiments in that the protrusion part PRU does not include the opening H and does not include the planarization layer PL. In FIG. 8, descriptions of portions overlapping with those described above will be omitted.

The protrusion part PRU in accordance with the third embodiments of the present disclosure may not include the opening H. Accordingly, the planarization layer PL may not be located inside the protrusion PRU. The planarization layer PL may not be located in the opening H of the protrusion PRU.

For example, in the display device DD in accordance with the third embodiments of the present disclosure, the protrusion part PRU may be located in the area in which the planarization layer PL is located, as compared with the above-described embodiments. In the display device DD in accordance with the third embodiments of the present disclosure, a surface at which the first electrode ELT1 and the light-emitting part EL are in contact with each other may entirely overlap with the protrusion part PRU.

The protrusion part PRU may include a flat surface at which the opening H is not formed. For example, the protrusion part PRU may include a flat upper surface (e.g., a surface that is not in contact with the pixel circuit layer PCL, and that is opposite to a surface that is in contact with the pixel circuit layer PCL) at which the opening H is not formed.

The protrusion part PRU may be formed through the same process as the first partition wall layer PW1. The protrusion part PRU may have substantially the same thickness as the first partition wall layer PW1. The protrusion part PRU may include the same material as the first partition wall layer PW1. The protrusion part PRU may include a metal material. In some embodiments, the protrusion part PRU may include aluminum (Al) or molybdenum (Mo).

The first electrode ELT1 may be entirely in contact with the protrusion part PRU. The first electrode ELT1 may entirely overlap the protrusion part PRU in a plan view. The light-emitting part EL may entirely overlap the protrusion part PRU in a plan view. The surface at which the first electrode ELT1 and the light-emitting part EL are in contact with each other may correspond to, or may substantially correspond to, the flat upper surface of the protrusion part PRU.

In the display device DD in accordance with the third embodiments of the present disclosure, as the protrusion part PRU protrudes from the pixel circuit layer PCL, the light-emitting part EL can be elevated as compared with the conventional display structure. Accordingly, a shadow effect due to a second partition wall layer PW2 can be reduced if the light-emitting part EL is deposited. In addition, a risk that light emitted from the light-emitting part EL will be blocked by the structure of the second partition wall layer PW2 can be reduced. Besides, as the protrusion part PRU includes the flat upper surface, the first electrode ELT1 can be formed on a roughly flat surface.

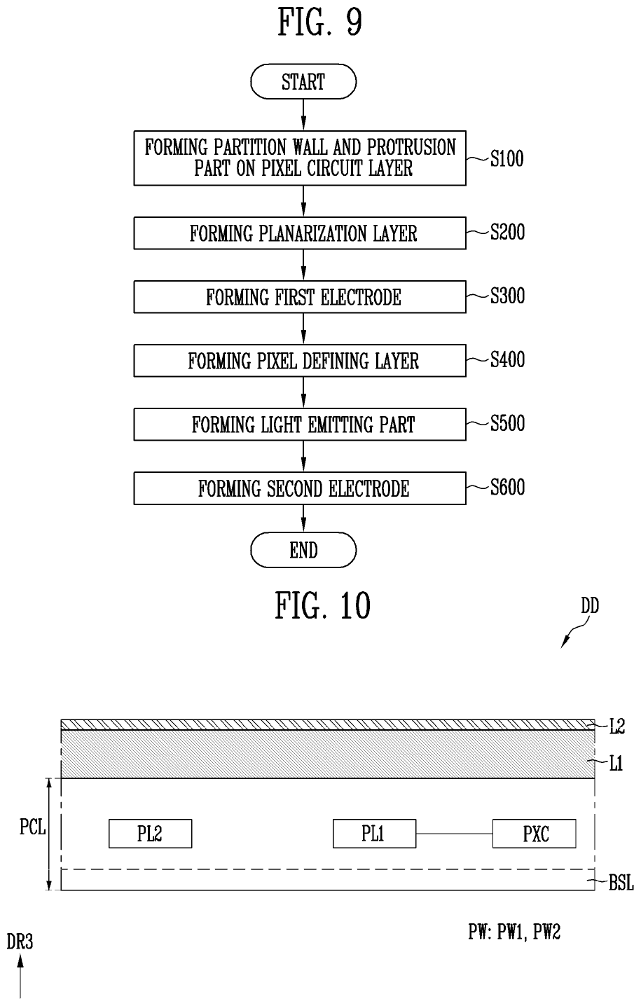

Hereinafter, a method of manufacturing the display device in accordance with the first embodiments of the present disclosure will be described with reference to FIGS. 9 to 16. FIG. 9 is a flowchart illustrating a method of manufacturing the display device in accordance with each of the first embodiments and the second embodiments of the present disclosure. FIGS. 10 to 16 are schematic sectional views illustrating process operations according to the method of manufacturing the display device in accordance with the first embodiments of the present disclosure.

Referring to FIG. 9, the method of manufacturing the display device DD may include operation S100 of forming a partition wall and a protrusion part on a pixel circuit layer, operation S200 of forming a planarization layer, operation S300 of forming a first electrode, operation S400 of forming a pixel-defining layer, operation S500 of forming a light-emitting part, and operation S600 of forming a second electrode.

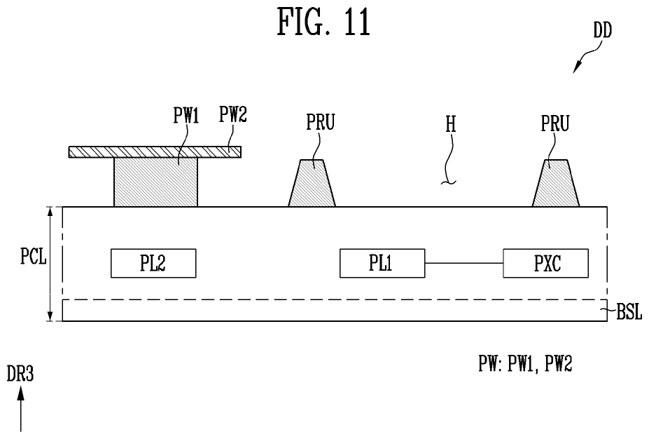

Referring to FIGS. 10 and 11, in the operation S100 of forming the partition wall and a protrusion part on the pixel circuit layer, a pixel circuit layer PCL including a pixel circuit PXC for driving light-emitting elements LD may be formed on a base layer BSL. The pixel circuit layer PCL may be formed to include conductive layers and insulating layers located between the conductive layers.

In some embodiments, components located on the base layer BSL may be formed through a patterning process (e.g., a photolithography process or the like) using a mask.

After the pixel circuit layer PCL is formed, a partition wall PW and a protrusion part PRU may be formed on the pixel circuit layer PCL. The partition wall PW and the protrusion part PRU may be formed through the same process. Thus, according to the method of manufacturing the display device DD in accordance with the present disclosure, processes can be simplified.

The operation of forming the partition wall PW and the protrusion part PRU may include an operation of depositing a first auxiliary layer L1 on the pixel circuit layer PCL, an operation of depositing a second auxiliary layer L2, an operation of etching the first auxiliary layer L1, and an operation of etching the second auxiliary layer L2.

The operation of depositing the first auxiliary layer L1 may include an operation of depositing a material for forming a first partition wall layer PW1 and the protrusion part PRU. In the present disclosure, at least one of a Chemical Vapor Deposition (CVD) process and/or an Atomic Layer Deposition (ALD) process may be used as a process of depositing a component of the display device DD. However, the present disclosure is not limited to a specific example.

The first auxiliary layer L1 may be deposited on the pixel circuit layer PCL. The first auxiliary layer L1 may include the same material as the first partition wall layer PW1 and the protrusion part PRU. For example, the first auxiliary layer L1 may include aluminum (Al) or molybdenum (Mo).

The operation of depositing the second auxiliary layer L2 may include an operation of depositing a material for forming the second partition wall layer PW2. The second auxiliary layer L2 may be deposited on the first auxiliary layer L1. The second auxiliary layer L2 may include the same material as the second partition wall layer PW2. For example, the second auxiliary layer L2 may include titanium (Ti).

The operation of etching the second auxiliary layer L2 may include an operation of etching at least a portion of the second auxiliary layer L2. The second auxiliary layer L2 may be etched to expose at least a portion of the first auxiliary layer L1. The second auxiliary layer L2 may be etched to form the second partition wall layer PW2. The second auxiliary layer L2 may be etched not to be located on the protrusion part PRU. The second auxiliary layer L2 may not be included in the protrusion part PRU. In the present disclosure, at least one of a wet etching and/or a dry etching may be used as an etching process. However, the present disclosure is not limited to a specific example.

The operation of etching the first auxiliary layer L1 may include an operation of etching at least a portion of the first auxiliary layer L1. The first auxiliary layer L1 may be etched to expose at least a portion of the pixel circuit layer PCL. The first auxiliary layer L1 may be etched to form the first partition wall layer PW1 and the protrusion part PRU. The first partition wall layer PW1 and the protrusion part PRU may be formed through the same process. Thus, a process for forming the first partition wall layer PW1 and the protrusion part PRU can be simplified.

The first partition wall layer PW1 may be etched relatively deeper (e.g., in the first direction DR1 and/or the second direction DR2), or to a greater extent, than the second partition wall layer PW2. As the first partition wall layer PW1 is etched deeper than that second partition wall layer PW2, the first partition wall layer PW1 may have a structure drawn inwardly than the second partition wall layer PW2. The first partition wall layer PW may be etched such that the second partition wall layer PW2 forms a tip (e.g., an overhang above the first partition wall layer PW1).

The first auxiliary layer L1 may be etched such that the protrusion part PRU forms an opening H. The first auxiliary layer L1 may be etched such that the partition wall PW and the protrusion part PRU are spaced apart from each other with respect to a direction (e.g., the first direction DR1 and/or the second direction DR2) in which a plane, on which the pixel circuit layer PCL is located, extends.

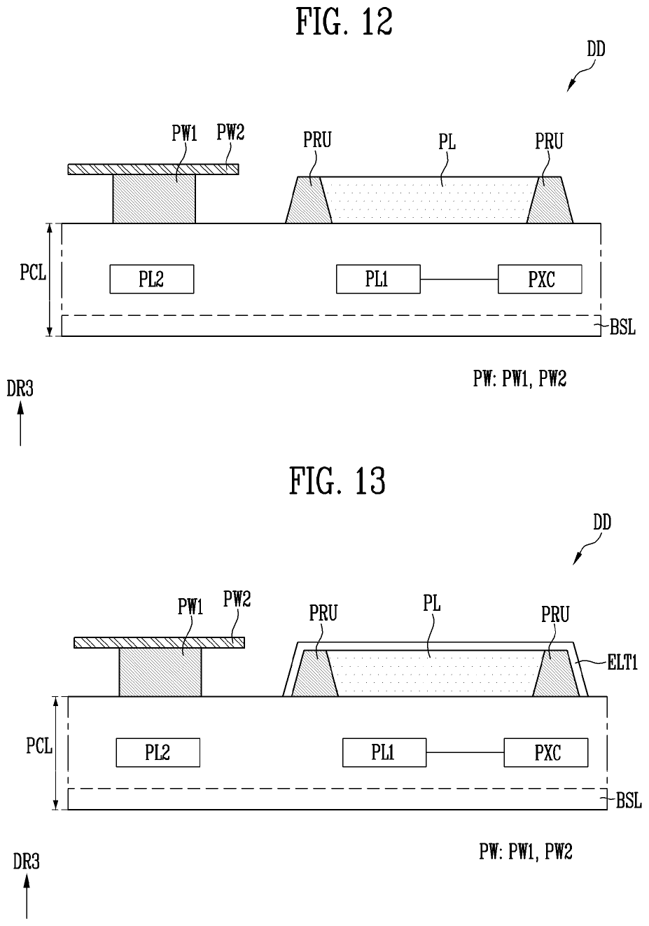

Referring to FIG. 12, in the operation S200 of forming the planarization layer, a planarization layer PL may be formed in the opening H of the protrusion part PRU. The planarization layer PL may be deposited on, or at, the opening H of the protrusion part PRU. The planarization layer PL may be deposited to have a thickness range that is similar to a thickness range of the protrusion part PRU. For example, the planarization layer PL may be deposited such that the planarization layer PL and the protrusion part PRU have a thickness difference included in a range of about 0 Å to about 1000 Å.

The planarization layer PL may include an organic material. Experimentally, if an organic layer including polyimide resin is etched, it may be easy for the organic layer to be removed through a light-exposure process.

Referring to FIG. 13, in the operation S300 of forming the first electrode, a first electrode ELT1 may be formed on the protrusion part PRU and the planarization PL. The first electrode ELT1 may be deposited to entirely cover the protrusion part PRU and the planarization PL. At least a portion of the first electrode ELT1 may be etched to expose at least a portion of the pixel circuit layer PCL.

In some embodiments, the first electrode ELT1 may be formed to have a single-layer structure or a multi-layer structure. For example, the first electrode ELT1 may be deposited to have a multi-layer structure in which aluminum (Al), silver (Ag), and Indium Tin Oxide (ITO) are sequentially located. However, the present disclosure is not limited thereto.

According to the presently described method of manufacturing the display device DD, the first electrode ELT1 is deposited on the protrusion part PRU and the planarization layer PL to be further elevated as compared with the conventional display structure. Each of one surface and the other surface of the first electrode ELT1 may be deposited to form an inclined surface.

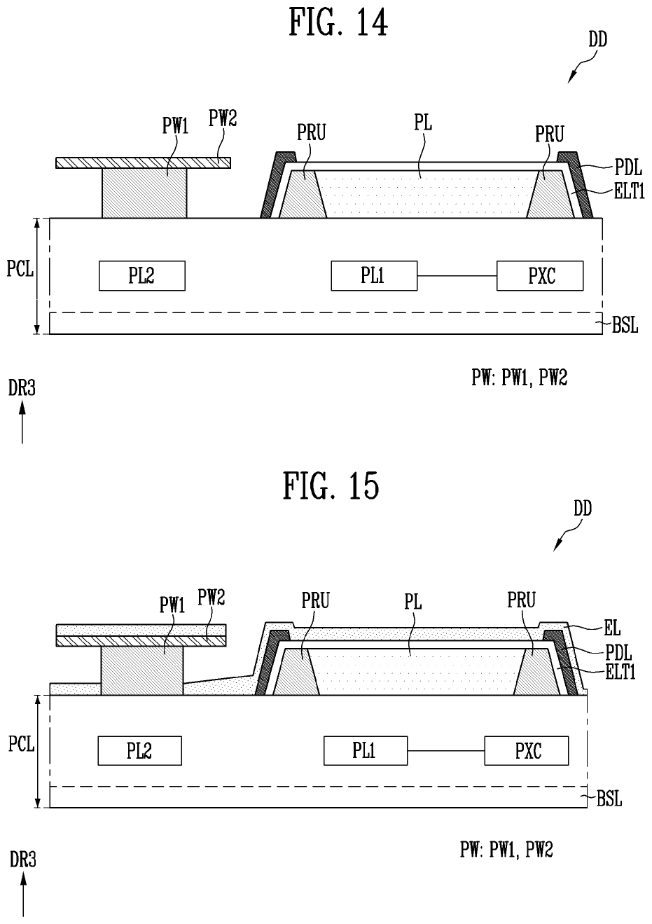

Referring to FIG. 14, in the operation S400 of forming the pixel-defining layer, a pixel-defining layer PDL may be formed on the first electrode ELT1. The pixel-defining layer PDL may be deposited to entirely cover the first electrode ELT1. The pixel-defining layer PDL may be etched to expose at least a portion of the first electrode ELT1. The pixel-defining layer PDL may be etched to cover one end portion and the other end portion of the first electrode ELT1.

Referring to FIG. 15, in the operation S500 of forming the light-emitting part, a light-emitting part EL may be deposited on the first electrode ELT1. The light-emitting part EL may be deposited on the planarization layer PL and the second partition wall layer PW2. The light-emitting part EL may be deposited to be in contact with one surface of the first electrode ELT1 and one surface of the second partition wall layer PW2. The light-emitting part EL may be deposited to expose at least a portion of a side surface of the first partition wall PW1.

As the light-emitting part EL is deposited on the first electrode ELT1 located high (e.g., elevated to a greater degree) as compared with the conventional display structure, the light-emitting part EL may also be located high as compared with the conventional display structure. For example, the light-emitting part EL overlapping with the planarization layer PL in a plan view may be deposited to be located higher than the first partition wall layer PW1. Thus, a shadow effect that an area in which the light-emitting part EL is deposited is covered by the second partition wall layer PW2 can be reduced. In addition, if light is emitted from the light-emitting part EL, a risk that the light emitted from the light-emitting part EL will be blocked by the structure of the second partition wall layer PW2 can be reduced.

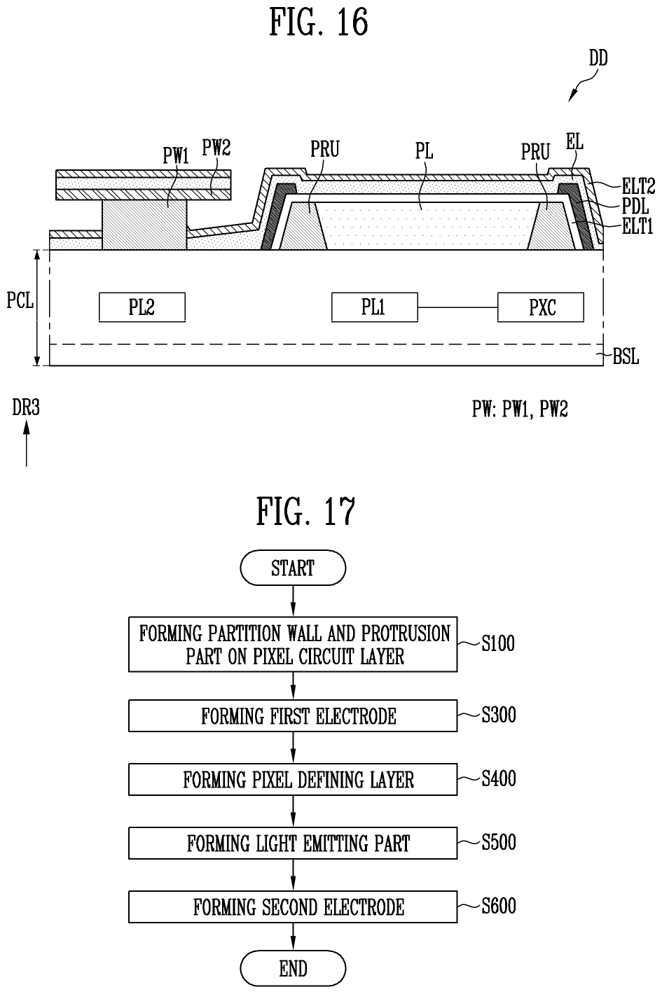

Referring to FIG. 16, in the operation S600 of forming the second electrode, a second electrode ELT2 may be formed on the light-emitting part EL. The second electrode ELT2 may be deposited on the light-emitting part EL. At least a portion of the second electrode ELT2 may be in contact with the light-emitting part EL located on the second partition wall layer PW2.

Hereinafter, a method of manufacturing the display device DD in accordance with the second embodiments of the present disclosure will be described with reference to FIGS. 7, 9, and 10. The method in accordance with the second embodiments are different from the method in accordance with the first embodiments in that the second auxiliary layer L2 is etched to form at least a portion of the protrusion part PRU. Hereinafter, descriptions of portions overlapping with those described above will not be repeated.

Referring to FIGS. 7, 9, and 10, in the operation S100 of forming the partition wall and the protrusion part on the pixel circuit layer, the protrusion part PRU may be formed to have a multi-layer structure including a first protrusion part PRU1 and a second protrusion part PRU2 located on the first protrusion part PRU1.

The first auxiliary layer L1 may be deposited on the pixel circuit layer PCL. The second auxiliary layer L2 may be deposited on the first auxiliary layer L1. The second auxiliary layer L2 may be etched to form the second partition wall layer PW2 and the second protrusion part PRU2. The second partition wall layer PW2 and the second protrusion part PRU2 may be formed through the same process. Thus, a process of forming the second partition wall layer PW2 and the second protrusion part PRU2 can be simplified.

Hereinafter, a method of manufacturing the display device DD in accordance with the third embodiments of the present disclosure will be described with reference to FIGS. 8, 10, and 17. FIG. 17 is a flowchart illustrating a method of manufacturing a display device in accordance with one or more embodiments of the present disclosure. The method in accordance with the third embodiments are different from the method in accordance with the first embodiments in that, if the first auxiliary layer L1 is etched, the first auxiliary layer L1 is etched such that the protrusion part PRU does not form the opening H. Hereinafter, descriptions of portions overlapping with those described above will not be repeated.

Referring to FIG. 17, the method of manufacturing the display device DD in accordance with the third embodiments of the present disclosure may omit the operation S200 of forming the planarization layer.

Referring to FIGS. 8 and 10, in the operation S100 of forming the partition wall and the protrusion part on the pixel circuit layer, the protrusion part PRU may be etched not to form the opening H when the first auxiliary layer L1 is etched to form the protrusion part PRU. The protrusion part PRU may be formed to include a flat upper surface.

As the protrusion part PRU does not form the opening H, the first electrode ELT1 may be deposited to be entirely in contact with the protrusion part PRU in the operation S300 of forming the first electrode. For example, the first electrode ELT1 may be entirely in contact with the flat upper surface of the protrusion part PRU (e.g., an entirety of the upper surface of the protrusion part PRU may be contacted by the first electrode ELT1). In addition, in the operation S500 of forming the light-emitting part, the light-emitting part EL may be deposited to entirely overlap with the protrusion part PRU in a plan view.

In accordance with the present disclosure, there can be provided a display device and a method of manufacturing a display device, which can improve the light emission efficiency of the display device while a light-emitting part is formed in a relatively wide area.

Embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, aspects described in connection with an embodiment may be used singly or in combination with aspects described in connection with other embodiments unless otherwise specifically indicated. Accordingly, it will be understood by those of skill in the art that various changes in form and details may be made without departing from the spirit and scope of the present disclosure as set forth in the following claims, with functional equivalents thereof to be included therein.

What is claimed is:

1. A display device comprising:
a pixel circuit layer;
a partition wall above the pixel circuit layer;
a protrusion part spaced apart from the partition wall in a planar direction, and defining an opening;
a planarization layer in the opening;
a first electrode having at least a portion above the planarization layer;
a light-emitting part having at least a portion above the first electrode; and
a second electrode having at least a portion above the light-emitting part.

2. The display device of claim 1, wherein the partition wall comprises:
a first partition wall layer above the pixel circuit layer; and
a second partition wall layer above the first partition wall layer.

3. The display device of claim 2, wherein a width the first partition wall layer is less than a width of the second partition wall layer.

4. The display device of claim 2, wherein the first partition wall layer comprises aluminum (Al) or molybdenum (Mo), and
wherein the second partition wall layer comprises titanium (Ti).

5. The display device of claim 2, wherein the protrusion part has a same height as the first partition wall layer.

6. The display device of claim 5, wherein the protrusion part and the first partition wall layer comprise a same material.

7. The display device of claim 2, wherein the protrusion part comprises:
a first protrusion part above the pixel circuit layer; and
a second protrusion part above the first protrusion part,
wherein the first protrusion part has a same height as the first partition wall layer, and
wherein the second protrusion part has a same height as the second partition wall layer.

8. The display device of claim 7, wherein the first protrusion part and the first partition wall layer comprise a same material, and
wherein the second protrusion part and the second partition wall layer comprise a same material.

9. The display device of claim 1, wherein the planarization layer fills the opening, comprises one flat surface, and comprises an organic material.

10. The display device of claim 9, wherein a difference between a thickness of the planarization layer and a thickness of the protrusion part is about 0 Å to about 1000 Å.

11. The display device of claim 10, wherein the first electrode and the protrusion part are electrically connected to each other.

12. A display device comprising:
a pixel circuit layer;
a partition wall above the pixel circuit layer, and comprising a first partition wall layer, and a second partition wall layer above the first partition wall layer;
a protrusion part spaced apart from the partition wall in a planar direction, and having a flat surface spaced from the pixel circuit layer;
a first electrode having at least a portion above the protrusion part;
a light-emitting part having at least a portion above the first electrode; and
a second electrode having at least a portion above the light-emitting part.

13. The display device of claim 12, wherein the protrusion part and the partition wall are at a same plane.

14. The display device of claim 13, wherein the first partition wall layer and the protrusion part comprise aluminum (Al), and
wherein the first electrode entirely overlaps with the protrusion part in a plan view.

15. A method of manufacturing a display device, the method comprising:
forming a partition wall and a protrusion part above a pixel circuit layer, and spaced apart in a planar direction, in a single process;
forming a first electrode above the protrusion part;
forming a light-emitting part above the first electrode; and
forming a second electrode above the light-emitting part.

16. The method of claim 15, wherein the forming of the partition wall and the protrusion part comprises:
depositing a first auxiliary layer above the pixel circuit layer;
depositing a second auxiliary layer above the first auxiliary layer;
etching the first auxiliary layer to form a first partition wall layer and the protrusion part on the pixel circuit layer; and
etching the second auxiliary layer to form a second partition wall layer above the first partition wall layer,
wherein the partition wall comprises the first partition wall layer and the second partition wall layer, and
wherein the first partition wall layer is etched more inwardly than the second partition wall layer.

17. The method of claim 15, wherein the forming of the partition wall and the protrusion part comprises:
depositing a first auxiliary layer above the pixel circuit layer;
depositing a second auxiliary layer above the first auxiliary layer;
etching the first auxiliary layer to form a first partition wall layer and a first protrusion part above the pixel circuit layer; and
etching the second auxiliary layer to form a second partition wall layer above the first partition wall layer and to form a second protrusion part on the first protrusion part, and
wherein the first protrusion part and the second protrusion part define an opening.

18. The method of claim 16, further comprising forming a planarization layer in an opening defined by the protrusion part by depositing the planarization layer such that the planarization layer and the protrusion part have a thickness difference of about 0 Å to about 1000 Å.

19. The method of claim 18, wherein the forming the first electrode comprises depositing the first electrode above the protrusion part such that at least a portion of one surface of the first electrode is spaced apart from the pixel circuit layer.

20. The method of claim 19, further comprising forming a pixel-defining layer comprising an inorganic material above the first electrode by depositing the pixel-defining layer above the first electrode, and etching the pixel-defining layer to expose at least a portion of the first electrode.
